(19) United States
(12) Patent Application Publication
(10) Pub. No.: US 2018/0019199 A1
(43) Pub. Date: Jan. 18, 2018

(54) SEMICONDUCTOR DEVICE HAVING REDISTRIBUTION LAYER WITH COPPER MIGRATION STOPPING

(71) Applicant: Chengdu Monolithic Power Systems Co., Ltd., Chengdu (CN)

(72) Inventors: Ming Xiao, Wuxi (CN); Zeqiang Yao, Chengdu (CN); Heng Li, Chengdu (CN); Fayou Yin, Chengdu (CN)

(21) Appl. No.: 15/644,403

(22) Filed: Jul. 7, 2017

(30) Foreign Application Priority Data
Jul. 14, 2016 (CN) 201610552274.0

(51) Int. Cl. H01L 23/498; H01L 21/311; H01L 21/768; H01L 21/56; H01L 21/02; H01L 23/31; H01L 23/00; H01L 21/48

(52) U.S. Cl. CPC H01L 23/49838; H01L 24/03; H01L 21/31111; H01L 21/486; H01L 21/56; H01L 24/13; H01L 24/11; H01L 24/05; H01L 21/02271; H01L 23/49827; H01L 23/3171; H01L 21/76871; H01L 2224/02381; H01L 2224/0239; H01L 2224/13611; H01L 2924/38

(57) ABSTRACT

A semiconductor device having a first dielectric layer and a redistribution layer. The redistribution layer has sidewalls and is formed on a passivation layer of the semiconductor device. The first dielectric layer covers the sidewalls of the redistribution layer. The first dielectric layer is insulative and has a physical property of stopping the migration of the redistribution layer.

### CROSS REFERENCE

This application claims the benefit of CN application No. 201610552274.0, filed on Jul. 14, 2016, and incorporated herein by reference.

### FIELD OF THE INVENTION

This disclosure generally relates to a semiconductor device and more particularly but not exclusively to a structure that connects an integrated circuit to an external circuit.

### BACKGROUND OF THE INVENTION

It is a significant trend of designing a semiconductor device to have smaller size with increasing density. To this end, in terms of packaging the semiconductor, the flip-chip package approach is more and more popularly used instead of the traditional wire bonding solution.

In the flip chip packaging approach, conductive bumps (solder balls or copper pillars with solder bumps etc.) are used to couple electrical terminals of a semiconductor device to a package lead frame, a package substrate or a printed circuit board. The semiconductor device may have a plurality of electrical terminals for receiving, sending or transferring signals.

As the size of a semiconductor device continues to decrease and the density of the semiconductor device continues to increase, the layout of metal trace is complex and the pitch between two adjacent metal traces is decreasing. Thus, migration phenomenon is easy to occur between adjacent metal traces coupled to different electrical terminals, especially when the semiconductor device works in high temperature and/or high humidity condition. Migration phenomenon may cause two adjacent metal traces coupled to different electrical terminals to be electrically shorted and may thus cause the failure of the semiconductor device.

In light of above, a novel structure is required to decrease or prevent the migration phenomenon.

### SUMMARY

Embodiments of the present invention are directed to a semiconductor device. The semiconductor device comprises a semiconductor substrate having an integrated circuit and a metal layer, wherein the metal layer is coupled to the integrated circuit. A passivation layer is formed on the semiconductor substrate. A plurality of vias are formed in the passivation layer to expose a plurality of surfaces of the metal layer. A redistribution layer is formed on a part of the passivation layer and in the plurality of vias, wherein the redistribution layer is coupled to the metal layer and has sidewalls and a top surface. A first dielectric layer is formed to cover the sidewalls of the redistribution layer, wherein the first dielectric layer is insulative and is configured to stop the migration of the redistribution layer.

Embodiments of the present invention are also directed to a semiconductor device. The semiconductor device comprises a semiconductor substrate having an integrated circuit and a metal layer, wherein the metal layer is coupled to the integrated circuit. A passivation layer is formed on the semiconductor substrate. A first connection structure and a second connection structure, wherein each of the connection structures comprises a plurality of vias formed in the passivation layer to expose a plurality of surfaces of the metal layer. A redistribution layer is formed on a part of the passivation layer and in the plurality of vias, wherein the redistribution layer is coupled to the metal layer and has sidewalls and a top surface. A first dielectric layer covering the sidewalls of the redistribution layer of each connection structure, wherein the first dielectric layer is insulative and is configured to stop the migration of the redistribution layer.

Embodiments of the present invention are directed to a method of manufacturing a semiconductor device. The method comprises: forming a passivation layer on a semiconductor substrate having a metal layer; forming a plurality of vias in the passivation layer to expose a plurality of surfaces of the metal layer; forming a redistribution layer on a part of the passivation layer and in the plurality of vias so that the redistribution layer is coupled to the metal layer, wherein the redistribution layer has sidewalls and a top surface; and forming a first dielectric layer on the sidewalls and the top surface of the redistribution layer and on the remaining part of the passivation layer, wherein the first dielectric layer is insulative and is configured to stop the migration of the redistribution layer.

With the above benefits, the novel structure of the present invention can stop migration as compared to the traditional technology, the failure or all the problems caused by the migration are thereby eliminated and the novel structure of the present invention has more reliability under high temperature and/or high humidity condition.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features.

FIG. 1 shows a cross-section of a portion of a semiconductor device 100 in accordance with an embodiment of the present invention.

FIG. 2 shows a cross-section of a portion of a semiconductor device 200 in accordance with an alternative embodiment of the present invention.

FIG. 3 shows a cross-section of a portion of a semiconductor device 300 in accordance with another alternative embodiment of the present invention.

FIGS. 4-14 show cross-sections of a flow diagram of manufacturing the semiconductor device 100 of FIG. 1 in accordance with an embodiment of the present invention.

FIGS. 15-16 show cross-sections of a flow diagram that are different from the semiconductor device 100 of FIG. 1 during manufacturing the semiconductor device 200 of FIG. 2 in accordance with an embodiment of the present invention.

The use of the same reference label in different drawings indicates the same or like components or structures with substantially the same function for the sake of simplicity.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled” as used herein, is defined as directly or indirectly connected in an electrical or non-electrical manner. The terms “a”, “an” and “the” include plural reference, and the term “in” includes “in” and “on”. The phrase “in one embodiment” as used herein does not necessarily refer to the same embodiment, although it may. The term “or” is an inclusive “or” operator, and is equivalent to the term “and/or” herein, unless the context clearly dictates otherwise. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. Those skilled in the art should understand that the meanings of the terms identified above do not necessarily limit the terms, but merely provide illustrative examples for the terms.

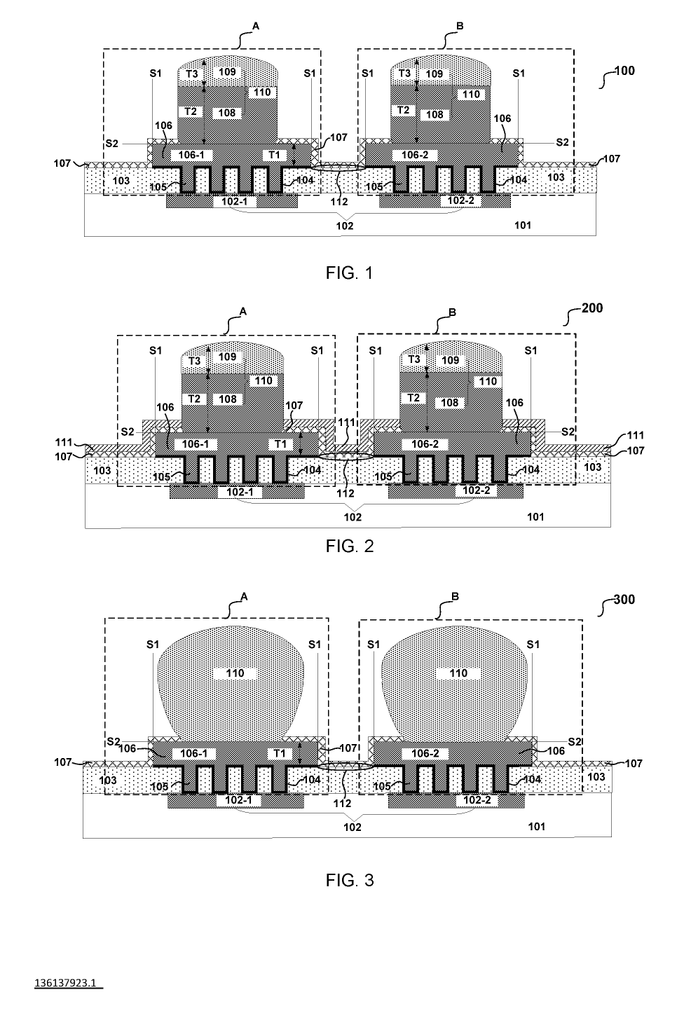

FIG. 1 shows a cross-section of a portion of a semiconductor device 100 in accordance with an embodiment of the present invention. The semiconductor device 100 comprises a semiconductor substrate 101. An integrated circuit that may comprise a DC-DC converter, a micro controller or other active or passive circuit elements may be manufactured in the semiconductor substrate 101. The semiconductor substrate 101 may further comprise inter-layer dielectric layers and a metal layer 102 over the integrated circuits formed in the semiconductor substrate 101. One skilled in the relevant art should recognize that the metal layer 102 may comprise a single metal layer or multi-metal layers. In the embodiments of multi-metal layers, herein the metal layer 102 refers to the top layer of the multi-metal layers. In one embodiment, the metal layer 102 comprises aluminum. One skilled in the relevant art should understand, the integrated circuit fabricated in the semiconductor substrate 101 may comprise a plurality of electrical terminals coupled to different signals respectively. In such embodiments, the metal layer 102 comprises many different routings (such as 102-1 and 102-2 shown in FIG. 1) to couple each of the electrical terminals of the integrated circuit to an external electrical circuit, such as a printed circuit board.

In the example of FIG. 1, the semiconductor device 100 further comprises a passivation layer 103 formed on the semiconductor substrate 101. In one embodiment, the passivation layer 103 comprises silicon oxide or silicon nitride. In one embodiment, the passivation layer 103 comprises a silicon oxide and silicon nitride stack, with the silicon oxide being formed on the semiconductor substrate 101 and the silicon nitride being formed on the silicon oxide.

Referring to the exemplary embodiment shown in FIG. 1, the semiconductor device 100 further comprises a plurality of vias 105, wherein the plurality of vias 105 are formed in the passivation layer 103 to expose a plurality of surfaces of the metal layer 102. In one embodiment, each of the vias 105 may have a different shape and size, such as a 3 μm*3 μm rectangle or a 6 μm*3 μm rectangle. One skilled in the relevant art should understand, although the plurality of vias 105 are illustrated in the embodiment of FIG. 1, it should be understood the illustration and description in this disclosure are not intended to be limiting and exclusive. One skilled in the relevant art should understand that a single via 105 may be formed in the semiconductor device 100. In the embodiment of FIG. 1, the semiconductor device 100 further comprises a redistribution layer 106 formed on a part of the passivation layer 103 and in the plurality of vias 105. The redistribution layer 106 has sidewalls S1 and a top surface S2. In one embodiment, the redistribution layer 106 may comprise copper. In another embodiment, the redistribution layer 106 has a thickness of T1 which is determined by design specifications. In one embodiment, T1 is in a range of 1 um to 30 um. In another embodiment, T1 is in a range of 5 um to 10 um.

Referring to the exemplary embodiment shown in FIG. 1, the semiconductor device 100 further comprises a seed layer 104, wherein the seed layer 104 may be located between the passivation layer 103 and the redistribution layer 106 and on the plurality of surfaces of the metal layer 102 that are exposed by the plurality of vias 105. The seed layer 104 can provide a good adhesion between the redistribution layer 106 and the passivation layer 103 and a good adhesion between the redistribution layer 106 and the metal layer 102. The seed layer 104 can be further used as a diffusion barrier layer to prevent the metal diffusion between the redistribution layer 106 and the passivation layer 103 and between the redistribution layer 106 and the metal layer 102. In one embodiment, the seed layer 104 comprises copper.

Continuing the introduction of FIG. 1, the semiconductor device 100 further comprises a conductive bump 110 which is formed on a part of the top surface of the redistribution layer 106 and is coupled to the redistribution layer 106. The conductive bump 110 comprises a copper pillar 108 and a solder bump 109, with the copper pillar 108 being formed on a part of the top surface of the redistribution layer 106 and coupled to the redistribution layer 106, and the solder bump 109 being formed on the copper pillar 108 and coupled to the copper pillar 108. In one embodiment, the copper pillar 108 may comprise copper. In another embodiment, the copper pillar 108 has a thickness of T2 which is determined by design specifications. In one embodiment, T2 is in a range of 35 um to 65 um. In another embodiment, T2 is in a range of 55 um to 65 um. The solder bump 109 may comprise tin (Sn) or tin (Sn) alloy in one embodiment. In another embodiment, the solder bump 109 has a thickness of T3 which is determined by design specifications. In one embodiment, T3 is in a range of 10 um to 50 um. In another embodiment, T3 is in a range of 25 um to 50 um. One of ordinary skill in the art should understand that the ranges for the thickness are only examples and are not intended to limit the invention.

In the embodiment of FIG. 1, the semiconductor device 100 further comprises a first dielectric layer 107 covering the sidewalls S1 of the redistribution layer 106, wherein the first dielectric layer 107 is insulative and is configured to stop the migration of the redistribution layer 106. In one embodiment, the first dielectric layer 107 further covers the remaining part of the passivation layer 103. In one embodiment, the first dielectric layer 107 further covers the remaining part of the top surface S2 of the redistribution layer 106.

In one embodiment, the first dielectric layer 107 comprises silicon dioxide. In an alternative embodiment, the first dielectric layer 107 comprises silicon nitride. In another alternative embodiment, the first dielectric layer 107 comprises silicon oxynitride. In one embodiment, the first dielectric layer 107 is formed by Chemical Vapor Deposition. In another embodiment, the first dielectric layer 107 is formed by TEOS-03 method. In other embodiments, the first dielectric layer 107 can be formed by any other suitable methods. In the embodiment shown in FIG. 1, the thickness of the first dielectric layer 107 is determined by design specifications. In one embodiment, the thickness of the first dielectric layer 107 is in a range of 1000 Å to 10000 Å. In another embodiment, the thickness of the first dielectric layer 107 is in a range of 1000 Å to 3000 Å.

In the embodiment of FIG. 1, the semiconductor device 100 comprises a first connection structure A and a second connection structure B at least. Each of the connection structures comprises the plurality of vias 105 and the redistribution layer 106. The plurality of vias 105 are formed in the passivation layer 103 to expose a plurality of surfaces of the metal layer 102. The redistribution layer 106 is formed on a part of the passivation layer 103 and in the plurality of vias 105, wherein the redistribution layer 106 has sidewalls S1 and a top surface S2. Each of the connection structures further comprises a conductive bump 110 formed on a part of the top surface of the redistribution layer 106. The semiconductor device 100 further comprises a first dielectric layer 107 covering the sidewalls of the redistribution layer 106 of each connection structure, wherein the first dielectric layer 107 is insulative and is configured to stop the migration of the redistribution layer 106. In one embodiment, the first dielectric layer 107 further covers the remaining part of the passivation layer 103. In one embodiment, the first dielectric layer 107 further covers the remaining part of the top surface S2 of the redistribution layer 106.

Still referring to FIG. 1, the semiconductor device 100 shown in FIG. 1 is ready to be molded by a mold compound (not show in FIG. 1) in a following package process. In the traditional technology, the passivation layer 103 and the mold compound contact directly and the interface between the passivation layer 103 and the mold compound is not tight enough, thus the migration is easy to occur. In the embodiment of this application, the redistribution layer 106 and the passivation layer 103 are covered by the first dielectric layer 107. The physical property of the first dielectric layer 107 makes the interface 112 (shown in FIG. 1) between the first dielectric layer 107 and the passivation layer 103 tight enough. It is not easy to form the migration path on the interface 112, as a result, the semiconductor device 100 of this application can stop the migration effectively.

FIG. 2 shows a cross-section of a portion of a semiconductor device 200 in accordance with an alternative embodiment of the present invention. Compared with the semiconductor device 100, the semiconductor device 200 in FIG. 2 further comprises a second dielectric layer 111 formed on the first dielectric layer 107. In one embodiment, the second dielectric layer 111 may comprises polyimide or PBO (Poly-p-PhenyleneBenzobisoxazole). In one embodiment, the thickness of the second dielectric layer 111 is in a range of 1 um to 20 um. In another embodiment, the thickness of the second dielectric layer 111 is in a range of 5 um to 10 um. The second dielectric Layer 111 can release the stress of the conductive bump 110, especially when the semiconductor device 200 works in a high temperature and/or a high humidity condition.

FIG. 3 shows a cross-section of a portion of a semiconductor device 300 in accordance with another alternative embodiment of the present invention. Compared with the semiconductor device 100 of FIG. 1, the semiconductor device 300 has another structure of conductive bump 110. This structure of conductive bump 110 comprises a solder ball and the solder ball comprises tin (Sn) or tin (Sn) alloy.

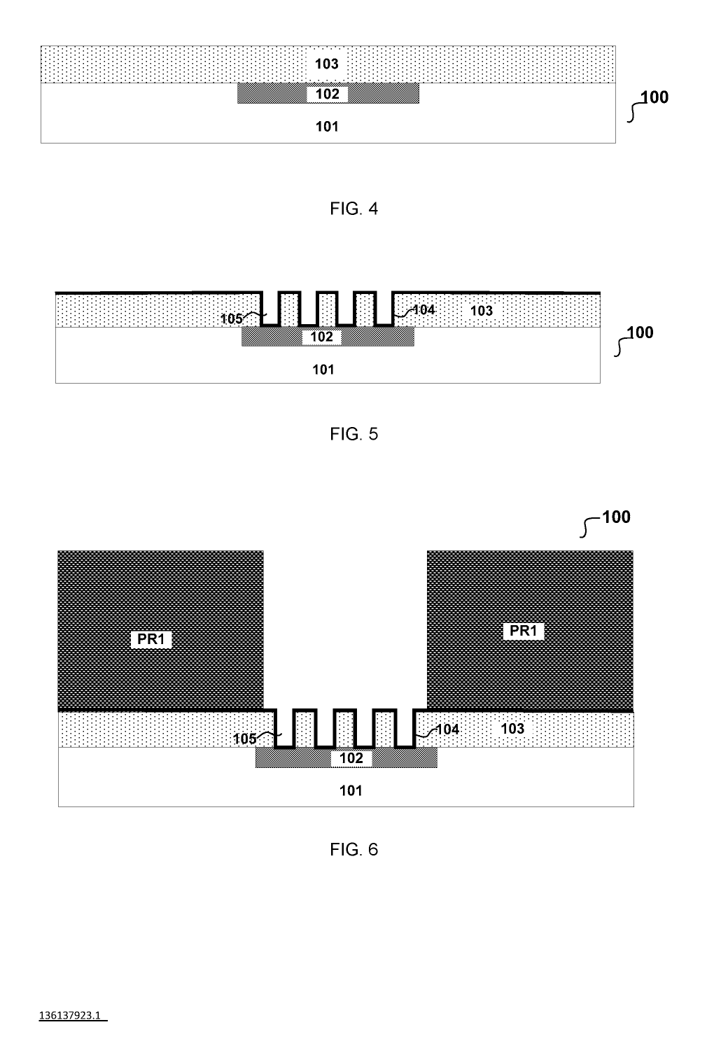

FIGS. 4-14 show cross-sections of a flow diagram of manufacturing the semiconductor device 100 of FIG. 1 in accordance with an embodiment of the present invention. For the sake of simplicity, a single connection structure is illustrated in FIGS. 4-14, but it should be understood that a plurality of connection structures maybe formed in semiconductor device 100.

Firstly, referring to FIG. 4, an integrated circuit and a metal layer 102 are formed in a semiconductor substrate 101, wherein the metal layer 102 is coupled to the integrated circuit. In one embodiment, the metal layer 102 may comprise a single metal layer or multi-metal layers. In the embodiments of multi-metal layers, herein the metal layer 102 refers to the top layer of the multi-metal layers. In one embodiment, the metal layer 102 comprises aluminum.

In the embodiment of FIG. 4, a passivation layer 103 is formed on the semiconductor substrate 101. In one embodiment, the passivation layer 103 may comprise a silicon oxide and silicon nitride stack, with the silicon oxide being formed on the semiconductor substrate 101 and the silicon nitride being formed on the silicon oxide.

Subsequently, referring to FIG. 5, a plurality of vias 105 are formed in the passivation layer 103 to expose a plurality of surfaces of the metal layer 102. In one embodiment, each of the vias 105 may have a different shape and size, such as a rectangle with 3 μm*3 μm or a rectangle with 6 μm*3 μm. Then a seed layer 104 is formed on the surface of the passivation layer 103 and on the plurality surfaces of the metal layer 102 that are exposed by the plurality of vias 105. In one embodiment, the seed layer 104 is formed by sputtering.

In subsequence, referring to FIG. 6, a first plating mask PR1 is formed on the seed layer 104 to define a region where a redistribution layer 106 is to be formed, wherein the first plating mask PR1 comprises a photoresist material.

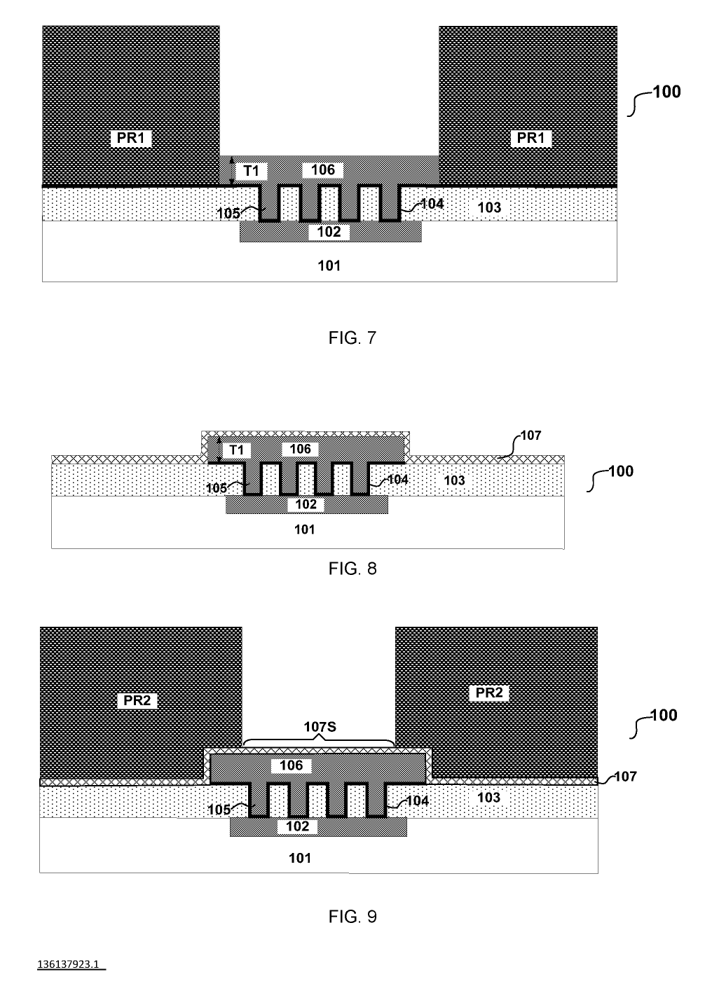

Then referring to FIG. 7, the redistribution layer 106 is formed by electroplating copper at the shielding of the first plating mask PR1. In one embodiment, the redistribution layer 106 has a thickness of T1 which is determined by design specifications. In one embodiment, T1 is in a range of 1 um to 30 um. In another embodiment, T1 is in a range of 5 um to 10 um.

Then referring to FIG. 8, the first plating mask PR1 and a part of the see layer 104 are removed. In one embodiment, the first plating mask PR1 is removed in a photoresist strip process. After removing the first plating mask PR1 and the part of the seed layer 104, a first dielectric layer 107 is formed to cover the redistribution layer 106 and the remaining part of the passivation layer 103 by deposition. Wherein the first dielectric layer 107 is insulative and is configured to stop the migration of the redistribution layer 106. In one embodiment, the first dielectric layer 107 may comprises silicon dioxide, silicon nitride or silicon oxynitride. In one embodiment, the first dielectric layer 107 may be formed by Chemical Vapor Deposition. In another embodiment, the first dielectric layer 107 is formed by TEOS-03 method. In addition, in some embodiments, the first dielectric layer 107 can be formed by any other suitable method.

Then referring to FIG. 9, a second plating mask PR2 that may comprise a photoresist material is formed on the first dielectric layer 107 to define a region where a conductive bump 110 is to be formed. In the embodiment of FIG. 9, the second plating mask PR2 exposes a region of the first dielectric layer 107 used to form a copper pillar 108 with covering the remaining region of the first dielectric layer 107.

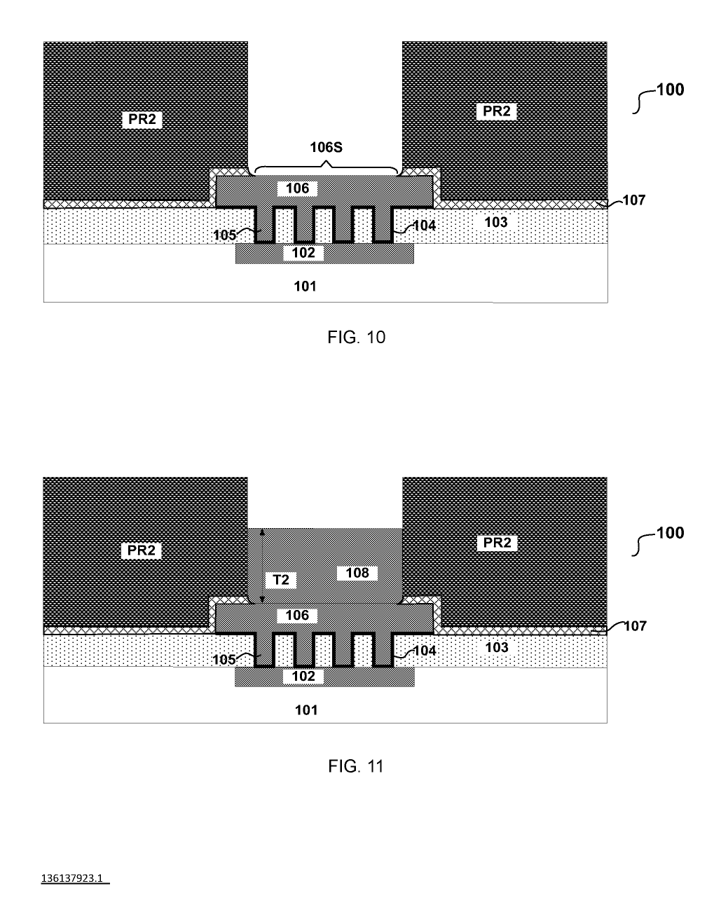

In the following step, a portion 107S of the first dielectric layer 107 is removed, referring to FIG. 10. A surface 106S of the redistribution layer 106 is exposed. In one embodiment, the portion 107S of the first dielectric layer 107 is removed by wet etching. In another embodiment, the portion 107S of the first dielectric layer 107 is removed by dry etching or any other suitable method.

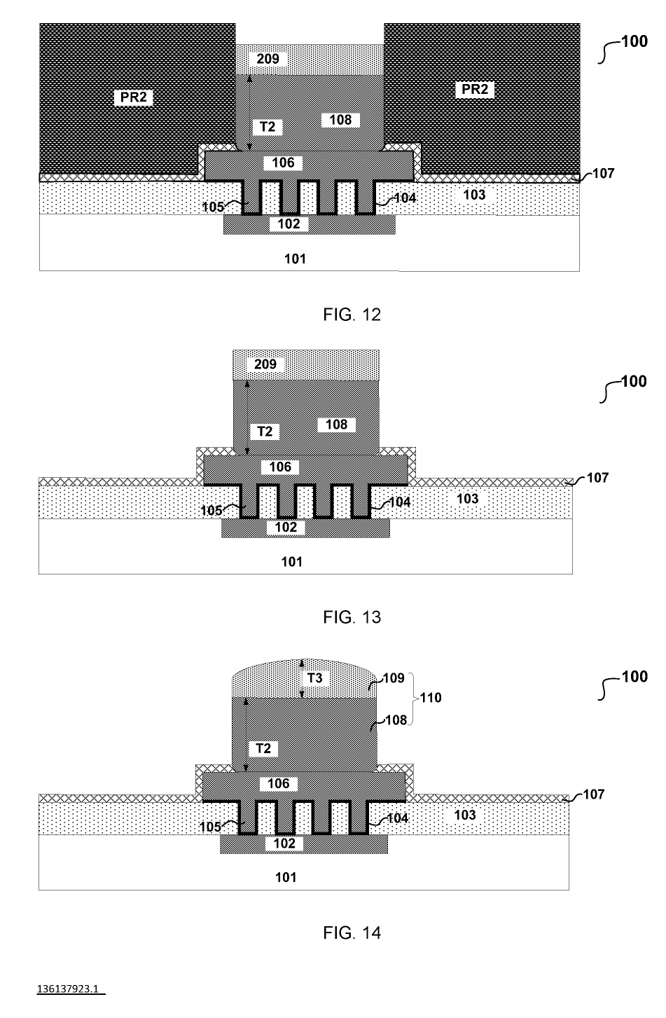

Subsequently, referring to FIG. 11 and FIG. 12, a conductive bump 110 is formed on the surface 106S of the redistribution layer 106 by electroplating. Forming the conductive bump 110 may comprise: forming a copper pillar 108 at first as FIG. 11 shows and then forming a solder layer 209 on the copper pillar 108 as FIG. 12 shows. In one embodiment, the copper pillar 108 may comprise copper and the copper pillar 108 has a thickness of T2 which is determined by design specification. In one embodiment, T2 is in a range of 35 um to 65 um. In another embodiment, T2 is in a range of 55 um to 65 um.

Then referring to FIG. 13, the second plating mask PR2 is removed in a photoresist strip process. The structure of FIG. 13 may be heated in a reflow process. In one embodiment, the reflow process may involve placing the structure of FIG. 13 in a reflow oven or any other suitable furnace so that the structure subjects to a thermal gradient. The heat in the reflow process causes the solder layer 209 to form a solder bump 109, thereby forming a structure of FIG. 14. The solder bump 109 may comprise tin (Sn) or tin (Sn) alloy, and the solder bump 109 has a thickness of T3 which is determined by design specifications. In one embodiment, T3 is in a range of 10 um to 50 um. In another embodiment, T3 is in a range of 25 um to 50 um. One of ordinary skill in the art should understand that the ranges for the thickness are only examples and are not intended to limit the invention.

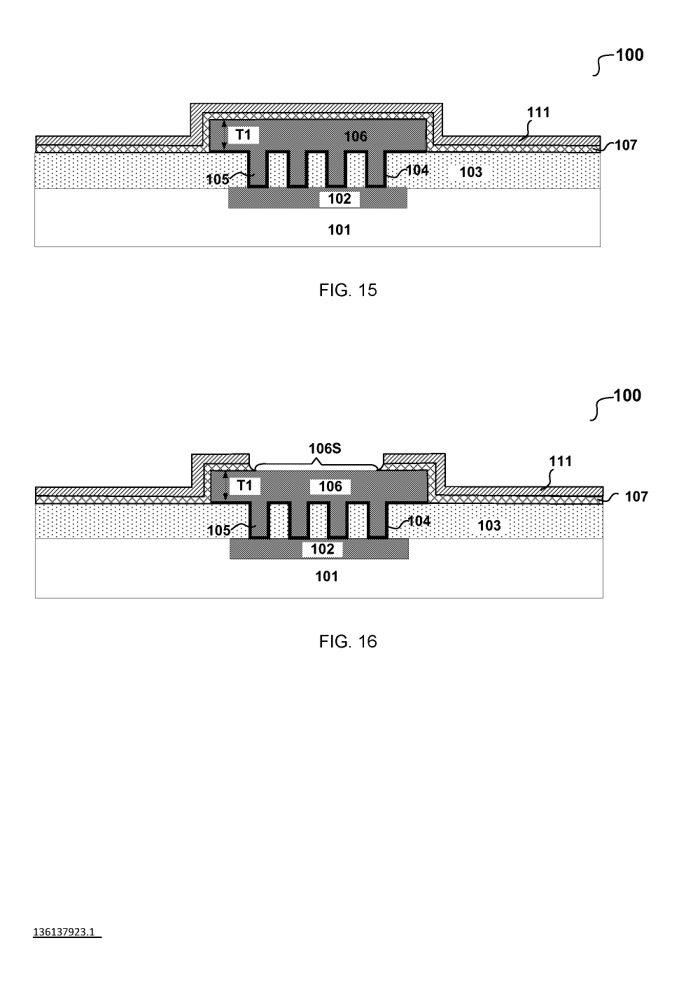

As stated above, the cross-sections of a flow diagram of manufacturing the semiconductor device 100 are shown in FIGS. 4-14. A method of manufacturing the semiconductor device 200 is similar to the method of manufacturing the semiconductor device 100 except replacing the step illustrated in FIG. 9 with the steps which will be illustrated later in FIGS. 15-16.

In the case of manufacturing the semiconductor device 200, after the first dielectric layer 107 is deposited on the redistribution layer 106 as illustrated in FIG. 8, the step described with reference to FIG. 15 may be performed to form a second dielectric layer 111 on the surface of the first dielectric layer 107. In one embodiment, the second dielectric layer 111 may comprise polyimide or PBO (Poly-p-PhenyleneBenzobisoxazole).

Then referring to FIG. 16, both the second dielectric layer 111 and the first dielectric layer 107 are etched to expose the surface 106S of the redistribution layer 106. Then referring back to the step as shown in FIG. 10, a conductive bump 110 is formed, and the following steps are as the same as the steps shown in FIGS. 11-14 of manufacturing the semiconductor device 100.

From the foregoing, it will be appreciated that specific embodiments of the present invention have been described herein for purposes of illustration, but that various modifications may be made without deviating from the spirit and scope of various embodiments of the present invention. Many of the elements of one embodiment may be combined with other embodiments in addition to or in lieu of the elements of the other embodiments. Accordingly, the present invention is not limited except as by the appended claims.

1. A semiconductor device, comprising:
a semiconductor substrate having an integrated circuit and a metal layer, wherein the metal layer is coupled to the integrated circuit;
a passivation layer on the semiconductor substrate;
a plurality of vias formed in the passivation layer to expose a plurality of surfaces of the metal layer;
a redistribution layer formed on a part of the passivation layer and in the plurality of vias, wherein the redistribution layer is coupled to the metal layer and has sidewalls and a top surface; and
a first dielectric layer covering the sidewalls of the redistribution layer, wherein the first dielectric layer is insulative and is configured to stop the migration of the redistribution layer.

2. The semiconductor device of claim 1, further comprising a conductive bump formed on a part of the top surface of the redistribution layer.

3. The semiconductor device of claim 2, wherein the conductive bump comprises:
a copper pillar formed on the part of the top surface of the redistribution layer; and
a solder bump formed on the copper pillar, wherein the solder bump comprises tin or tin alloy.

4. The semiconductor device of claim 2, wherein the conductive bump comprises a solder ball formed on the part of the top surface of the redistribution layer, wherein the solder ball comprises tin or tin alloy.

5. The semiconductor device of claim 1, wherein the first dielectric layer further covers the remaining part of the passivation layer.

6. The semiconductor device of claim 2, wherein the first dielectric layer further covers the remaining part of the top surface of the redistribution layer.

7. The semiconductor device of claim 1, wherein the first dielectric layer comprises silicon dioxide, silicon nitride or silicon oxynitride.

8. The semiconductor device of claim 1, wherein the thickness of the first dielectric layer is in a range of 1000 Å to 10000 Å.

9. The semiconductor device of claim 1, further comprisinga second dielectric layer covering the first dielectric layer, wherein the second dielectric layer comprises polyimide or PBO.

10. A semiconductor device, comprising:
a semiconductor substrate having an integrated circuit and a metal layer, wherein the metal layer is coupled to the integrated circuit;
a passivation layer on the semiconductor substrate;
a first connection structure and a second connection structure, wherein each of the connection structures comprises:
a plurality of vias formed in the passivation layer to expose a plurality of surfaces of the metal layer; and
a redistribution layer formed on a part of the passivation layer and in the plurality of vias, wherein the redistribution layer is coupled to the metal layer and has sidewalls and a top surface; and
a first dielectric layer covering the sidewalls of the redistribution layerof each connection structure, wherein the first dielectric layer is insulative and is configured to stop the migration of the redistribution layer.

11. The semiconductor device of claim 10, wherein each of the connection structures further comprises a conductive bump formed on a part of the top surface of the redistribution layer.

12. The semiconductor device of claim 10, wherein the first dielectric layer further covers the remaining part of the passivation layer.

13. The semiconductor device of claim 11, wherein the first dielectric layer further covers the remaining part of the top surface of the redistribution layer.

14. The semiconductor device of claim 10, wherein the first dielectric layer comprises silicon dioxide, silicon nitride or silicon oxynitride.

15. The semiconductor device of claim 10, further comprisinga second dielectric layer covering the first dielectric layer, wherein the second dielectric layer comprises polyimide or PBO.

16. A method of manufacturing a semiconductor device, comprising:
forming a passivation layer on a semiconductor substrate having a metal layer;
forming a plurality of vias in the passivation layer to expose a plurality of surfaces of the metal layer;
forming a redistribution layer on a part of the passivation layer and in the plurality of vias so that the redistribution layer is coupled to the metal layer, wherein the redistribution layer has sidewalls and a top surface; and
forming a first dielectric layer on the sidewalls and the top surface of the redistribution layer and on the remaining part of the passivation layer, wherein the first dielectric layer is insulative and is configured to stop the migration of the redistribution layer.

17. The method of claim 16, wherein the first dielectric layer comprises silicon dioxide, silicon nitride or silicon oxynitride.

18. The method of claim 16,further comprising forming a second dielectric layer on the first dielectric layer, wherein the second dielectric layer comprises polyimide or PBO.

19. The method of claim 16, wherein the first dielectric layer is formed by Chemical Vapor Deposition.

20. The method of claim 16, further comprising:
removing a part of the first dielectric layer on the top surface of the redistribution layer to expose a part of the redistribution layer; and
forming a conductive bump on the exposed part of the redistribution layer.
